(19) United States
(12) Patent Application Publication
(10) Pub. No.: US 2025/0204103 A1
(43) Pub. Date: Jun. 19, 2025

(54) Carrier Confinement Structure of AlInGaP MicroLEDs

(71) Applicant: Lumileds LLC, San Jose, CA (US)

(72) Inventors: Ted Chung, Santa Clara, CA (US); Juan Cai, San Jose, CA (US)

(73) Assignee: Lumileds LLC, San Jose, CA (US)

(21) Appl. No.: 18/541,732

(22) Filed: Dec. 15, 2023

(51) Int. Cl. H01L 33/50; H01L 33/06; H01L 33/30

(52) U.S. Cl. CPC H10H 20/8512; H10H 20/812; H10H 20/824

(57) ABSTRACT

AlInGaP microLEDs comprise AlInGaP quantum dots disposed in one or more quantum wells in the microLED light emitting active region. The quantum dots trap and confine carriers (electrons and holes) that are injected into the light emitting active region during operation of the microLED, preventing the confined carriers from moving laterally along the quantum wells to reach nonradiative recombination centers at the perimeter surfaces of the device and thereby increasing the light emitting efficiency of the microLED.

### FIELD OF THE INVENTION

The invention relates generally to AlInGaP microLEDs, and to arrays, light sources, and displays comprising AlInGaP microLEDs.

### BACKGROUND

Direct emitting (i.e., not phosphor-converted) microLEDs formed in the AlInGaP material system are high-performance red emitters that may be used in microLED display device applications such as, for example, microLED display engines, direct-view displays, and augmented reality (AR), virtual reality (VR), and mixed reality (MR) systems. Such applications may include head-mounted (HMD) display systems.

In operation of an LED, a forward bias is applied across a diode junction in the LED and radiative recombination of injected electrons and holes results in the emission of light. In general, the desired radiative recombination process competes with non-radiative recombination processes in which injected electrons and holes recombine without emitting light. Such non-radiative recombination undesirably reduces the quantum efficiency with which the LED emits light.

Nonradiative recombination in an LED is promoted by non-radiative recombination centers (e.g., defects, dangling bonds, and surfaces states) located at or near perimeter semiconductor surfaces of the LED and resulting for example from etch damage that occurs during fabrication of the device. Because nonradiative recombination occurs primarily near device perimeter semiconductor surfaces, its undesirable effect on device quantum efficiency increases significantly as device size decreases and the surface to volume ratio of the device consequently increases. Individual AlInGaP microLEDs may have sizes of, for example, less than 50 microns and as a result can suffer from low quantum efficiency due to increased non-radiative recombination of carriers at the device perimeter.

### SUMMARY

This specification discloses AlInGaP microLEDs comprising AlInGaP quantum dots (QDs) disposed in one or more quantum wells (QWs) in the microLED light emitting active region. The quantum dots trap and confine carriers (electrons and holes) that are injected into the light emitting active region during operation of the microLED, preventing the confined carriers from moving laterally along the quantum wells to reach nonradiative recombination centers at the perimeter surfaces of the device and thereby increasing the light emitting efficiency of the microLED. These microLEDs may have largest transverse dimensions (i.e., parallel to the layers in the epitaxial structure of the LED) of, for example, ≤50 microns, ≤30 microns, ≤10 microns, ≤5 microns, or ≤1 micron.

A microLED as described above comprises a stack of semiconductor layers comprising an n-type (AlₓₙGa₁₋ₓₙ)_{yn}In_{1-yn}P layer, a p-type (AlₓₚGa₁₋ₓₚ)_{yp}In_{1-yp}P layer, and an active region disposed between the n-type (AlₓₙGa₁₋ₓₙ)_{yn}In_{1-yn}P layer and the p-type (AlₓₚGa₁₋ₓₚ)_{yp}In_{1-yp}P layer. The active region comprises at least one (Al_{xqw}Ga_{1-xqw})_{yqw}In_{1-yqw}P quantum well layer. A plurality of compressively strained Ga_{yqd}In_{1-yqd}P quantum dots is disposed in at least one of the quantum well layers. The subscripts characterizing the compositions of these layers satisfy the following constraints: 0≤xn≤1, 0≤yn<1, 0≤xp≤1, 0≤yp<1, 0≤xqw≤0.3, 0≤yqw<1, and 0≤yqd<yqw.

Significantly, the relation 0≤yqd<yqw requires that the quantum dots comprise more Indium than does the quantum well layer. As a result, during manufacture of the microLED when the quantum dot material is grown on or in a layer of the quantum well material the lattice mismatch between the crystal structure of the quantum dot material and the crystal structure of the quantum well material causes compressive strain on the quantum dot material that induces it to self-assemble as discrete quantum dots rather than form as a continuous layer. This is discussed further in the detailed description below.

An active region quantum well layer in the microLED may have a thickness of, for example, about 1.5 nanometers (nm) to about 10 nm, or about 3 nm to about 10 nm. Quantum dots disposed in an active region quantum well layer of the microLED may have transvers dimensions in the plane of the quantum well layer of, for example, about 2 nm to about 200 nm.

In operation, the microLED may for example emit red light. The emitted light may have for example a peak wavelength of about 580 nm to about 660 nm, for example 630 nm or 650 nm.

A plurality of such microLEDs may be arranged in a light emitting array, optionally in combination with microLEDs formed in other material systems (e.g., AlInGaN) and configured to emit other wavelengths of light to form (e.g., RGB) pixels. Such an array may be used in a display device, for example, with the AlInGaP microLEDs arranged as pixel red emitters.

Referring again to the structure of the microLED, in some variations xn=xp=1 (i.e., there is no Gallium in the n-type and p-type layers cited above).

In some variations 0.50≤yn≤0.51 and/or 0.50≤yp≤0.51 (i.e., the n-type layer, the p-type layer, or both the n-type layer and the p-type layer are lattice matched to crystalline Gallium Arsenide (GaAs), which is typically used as a growth substrate during manufacture of the microLED).

In some variations, 0.50≤yqw≤0.51 (i.e., the quantum well layer is lattice matched to GaAs). Alternatively, in some variations 0.40≤yqw≤0.5 (i.e., the quantum well layer is lattice mismatched to GaAs and consequently compressively strained).

Typically 0≤yqd<0.5. In some variations, yqd=0 (i.e., the quantum dots are formed from InP). In other variations yqd>0 (i.e., the quantum dots include some Gallium in addition to Indium and Phosphor).

In some variations 0.50≤yn≤0.51 and/or 0.50≤yp≤0.51 (i.e., the n-type layer, the p-type layer, or both the n-type layer and the p-type layer are lattice matched to GaAs), 0.50≤yqw≤0.51 (i.e., the quantum well layer is lattice matched to GaAs), and 0≤yqd<0.5 (i.e., the quantum dots are lattice mismatched to GaAs and to the QW layer and consequently compressively strained). In some of these variations yqd=0 (i.e., the quantum dots are formed from InP). In other of these variations yqd>0 (i.e., the quantum dots include some Gallium in addition to Indium and Phosphor).

In some variations 0.50≤yn≤0.51 and/or 0.50≤yp≤0.51 (i.e., the n-type layer, the p-type layer, or both the n-type layer and the p-type layer are lattice matched to GaAs), and 0.40≤yqw≤0.5 (i.e., the quantum well layer is lattice mismatched to GaAs and consequently compressively strained). In some of these variations yqd=0 (i.e., the quantum dots are formed from InP). In other of these variations yqd>0 (i.e., the quantum dots include some Gallium in addition to Indium and Phosphor).

In some variations the at least one (Al_{xqw}Ga_{1-xqw})_{yqw}In_{1-yqw}P quantum well layer is one of a plurality of (Al_{xqw}Ga_{1-xqw})_{yqw}In_{1-yqw}P quantum well layers. In such variations the microLED comprises one or more (Al_{xqb}Ga_{1-xqb})_{yqb}In_{1-yqb}P quantum barrier layers each disposed between two adjacent ones of the quantum well layers, wherein xqb>xqw.

The quantum barrier layers may for example have composition (Al_{xqb}Ga_{1-xqb})_{0.51}In_{0.49}P (i.e., be lattice matched to GaAs) with 0.3≤xqb≤0.8.

In some of the variations comprising multiple quantum well layers, each of the (Al_{xqw}Ga_{1-xqw})_{yqw}In_{1-yqw}P quantum well layers comprises a plurality of compressively strained Ga_{yqd}In_{1-yqd}P quantum dots disposed in the quantum well layer.

In some variations comprising multiple quantum well layers, only a subset of the (Al_{xqw}Ga_{1-xqw})_{yqw}In_{1-yqw}P quantum well layers located closer to the n-type (AlₓₙGa₁₋ₓₙ)_{yn}In_{1-yn}P layer than to the p-type (AlₓₚGa₁₋ₓₚ)_{yp}In_{1-yp}P layer comprises a plurality of compressively strained Ga_{yqd}In_{1-yqd}P quantum dots disposed in the quantum well layer.

In some variations comprising multiple quantum well layers, only a subset of the (Al_{xqw}Ga_{1-xqw})_{yqw}In_{1-yqw}P quantum well layers located closer to the p-type (AlₓₚGa₁₋ₓₚ)_{yp}In_{1-yp}P layer than to the n-type (AlₓₙGa₁₋ₓₙ)_{yn}In_{1-yn}P layer comprises a plurality of compressively strained Ga_{yqd}In_{1-yqd}P quantum dots disposed in the quantum well layer.

The AlInGaP microLEDs disclosed herein may be used for example in the various devices and applications listed above in the Background section.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example microLED.

FIGS. 2A and 2B show, respectively, cross-sectional and top schematic views of an array of microLEDs. FIG. 2C shows a schematic top view of a microLED wafer from which microLED arrays such as those illustrated in FIGS. 2A and 2B may be formed.

FIG. 3A shows a schematic top view of an electronics board on which an array of microLEDs may be mounted, and FIG. 3B similarly shows an array of microLEDs mounted on the electronic board of FIG. 3A.

FIG. 4A shows a schematic cross-sectional view of an array of microLEDs arranged with respect to waveguides or microlenses and a projection lens. FIG. 4B shows an arrangement similar to that of FIG. 4A, without the waveguides or microlenses.

FIG. 5 schematically illustrates an example display (e.g., AR/VR/MR) system that includes an array of microLEDs.

FIG. 6A shows a schematic cross-sectional view of an example AlInGaP microLED structure comprising quantum dots in its active region. FIG. 6B shows a schematic cross-sectional view of a portion of the microLED structure of FIG. 6A comprising the quantum dots.

FIGS. 7A-7C show schematic cross-sectional view of three example AlInGaP microLED active regions, each of which comprises a stack of quantum well and quantum barrier layers with quantum dots disposed in at least one of the quantum well layers.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

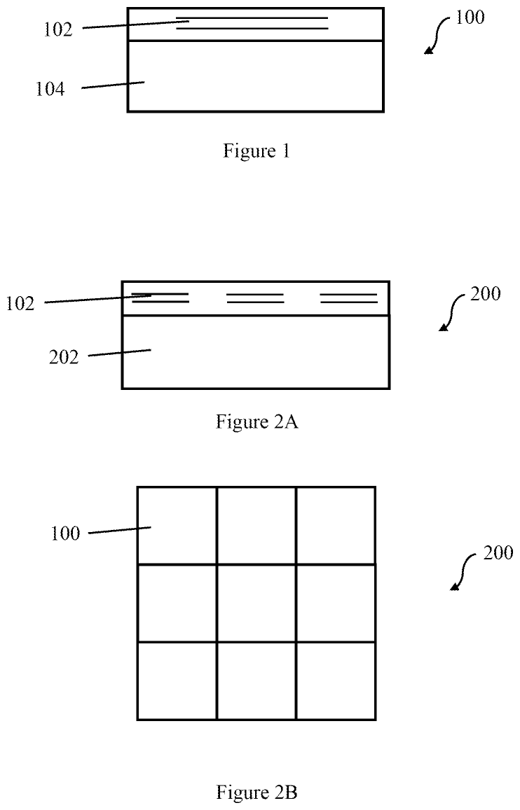

FIG. 1 shows an example of an individual microLED 100 comprising a light emitting semiconductor diode (LED) structure 102 disposed on a substrate 104. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

Although this specification focuses on direct emitting AlInGaP microLEDs, more generally direct emitting and phosphor converted microLEDs (pc-microLEDs) may be formed in other material systems, such as for example AlInGaN. Generally, a pc-microLED comprises a phosphor material that absorbs light from the microLED and in response emits longer wavelength light that forms all or part of the light output from the pc-microLED. Such pc-microLEDs may comprise ultraviolet or blue emitting AlInGaN microLEDs in combination with a phosphor, for example. The AlInGaP microLEDs disclosed in this specification may be used in combination with direct emitting microLEDs formed in such other material systems and/or with pc-microLEDs. For example, red emitting AlInGaP microLEDs as disclosed in this specification may be used in combination with direct emitting AlInGaN microLEDs or phosphor converted microLEDs (pc-microLEDs) that emit blue or green light to form RGB pixels for displays.

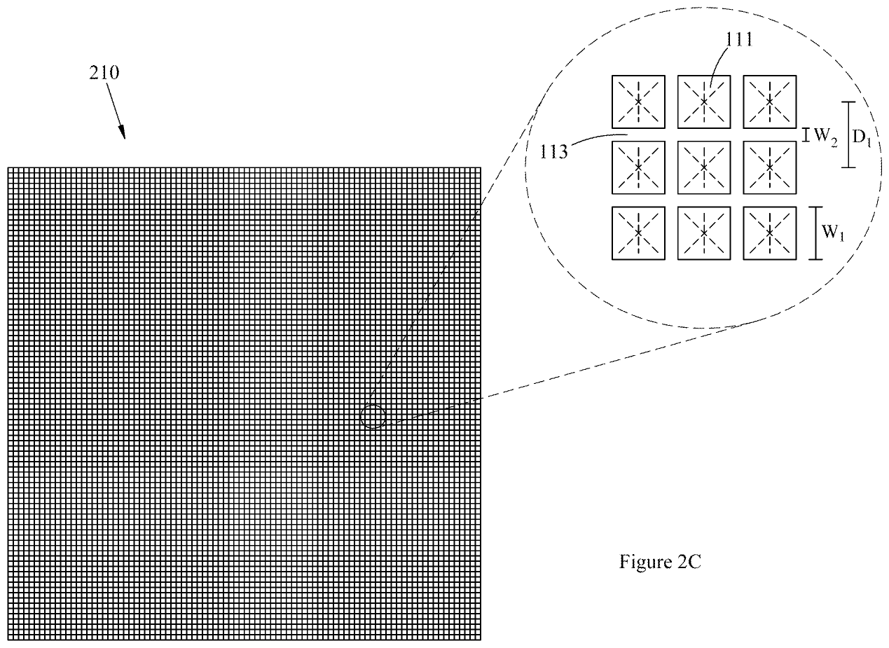

FIGS. 2A-2B show, respectively, cross-sectional and top views of an array 200 of microLEDs 100 disposed on a substrate 202. Such an array may include any suitable number of microLEDs arranged in any suitable manner. In the illustrated example the array is depicted as formed monolithically on a shared substrate, but alternatively an array of microLEDs may be formed from separate individual microLEDs. Substrate 202 may optionally comprise CMOS circuitry for driving the microLEDs and may be formed from any suitable materials.

Although FIGS. 2A-2B show a three-by-three array of nine microLEDs, such arrays may include for example tens, hundreds, or thousands of microLEDs. Individual microLEDs may have widths (e.g., side lengths) in the plane of the array of, for example, less than or equal to 50 microns, less than or equal to 30 microns, less than or equal to 10 microns, or less than or equal to 1 micron. The microLEDs in such an array may be spaced apart from each other by streets or lanes having a width in the plane of the array of, for example, hundreds of microns, less than or equal to 100 microns, less than or equal to 50 microns, less than or equal to 30 microns, less than or equal to 10 microns, or less than or equal to 5 microns. Although the illustrated examples show rectangular microLEDs arranged in a symmetric matrix, the microLEDs and the array may have any suitable shape or arrangement. Although the illustrated examples show an array in which all microLEDs are of the same size, microLEDs in an array may differ in size.

Further, as noted above such an array may include microLEDs that are formed from different material systems and emit different colors of light and/or include pc-microLEDs.

FIG. 2C shows a schematic top view of a portion of a microLED wafer 210 (e.g., an AlInGaP microLED wafer) from which microLED arrays such as those illustrated in FIGS. 2A and 2B may be formed. FIG. 2C also shows an enlarged 3×3 portion of the wafer. In the example wafer individual microLEDs 111 having side lengths (e.g., widths) of W₁ are arranged as a square matrix with neighboring microLEDs having a center-to-center distances D₁ and separated by lanes 113 having a width W₂. W₁ may be, for example, less than or equal to 50 microns, less than or equal to 30 microns, less than or equal to 10 microns, less than or equal to 5 microns, or less than or equal to 1 micron. W₂ may be, for example, hundreds of microns, less than or equal to 100 microns, less than or equal to 50 microns, less than or equal to 10 microns, or less than or equal to 5 microns. D₁=W₁+W₂.

An array may be formed, for example, by separating wafer 210 into individual microLEDs and arranging the microLEDs on a substrate (e.g., in combination with microLEDs formed in other material systems and/or pc-microLEDs). Alternatively, an array may be formed from the entire wafer 210, or by dividing wafer 210 into smaller arrays of microLEDs.

The individual microLEDs or pc-microLEDs in an array may be individually operable (addressable) and/or may be operable as part of a group or subset of (e.g., adjacent) microLEDs or pc-microLEDs in the array. A single individually operable microLED or pc-microLED or a group of adjacent such microLEDs and/or pc-microLEDs may correspond to a single pixel (picture element) in a display. For example, a group of three individually operable adjacent microLEDs and/or pc-microLEDs comprising a red emitter, a blue emitter, and a green emitter may correspond to a single color-tunable pixel in a display.

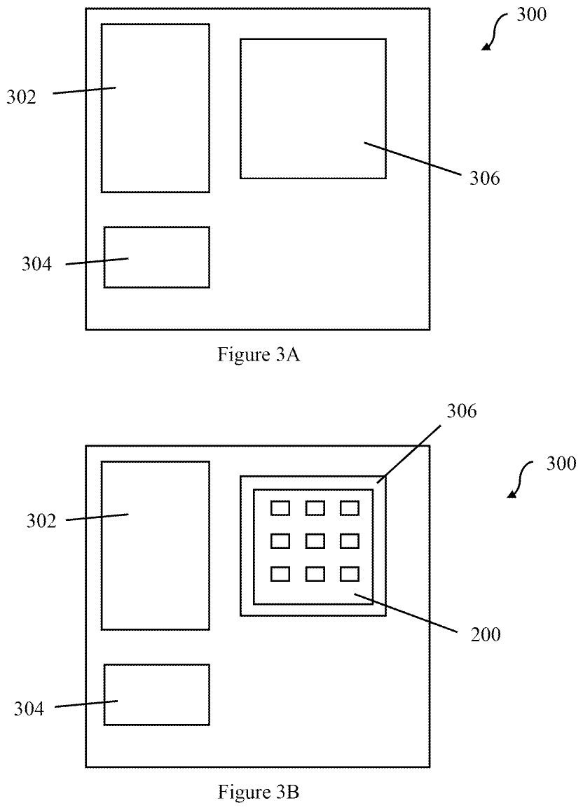

As shown in FIGS. 3A-3B, a microLED array 200 may for example be mounted on an electronics board 300 comprising a power and control module 302, a sensor module 304, and an attach region 306. Power and control module 302 may receive power and control signals from external sources and signals from sensor module 304, based on which power and control module 302 controls operation of the microLEDs and/or pc-microLEDs in the array. Sensor module 304 may receive signals from any suitable sensors, for example from temperature or light sensors. Alternatively, array 200 may be mounted on a separate board (not shown) from the power and control module and the sensor module.

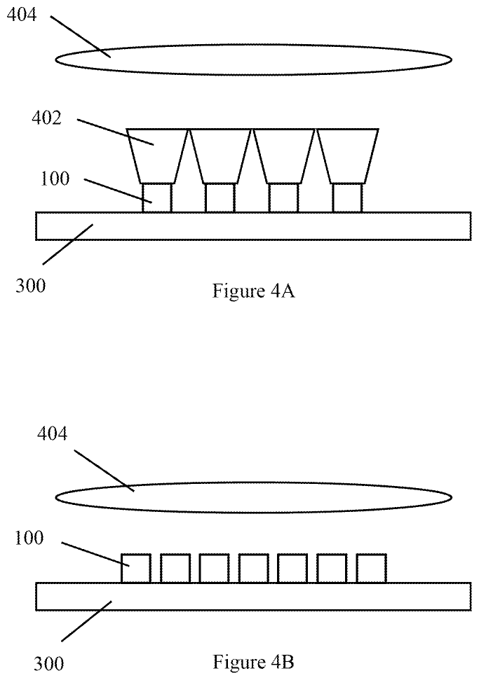

As shown in FIG. 4A, individual microLEDs or pc-microLEDs may optionally incorporate or be arranged in combination with a lens (e.g., microlens) or other optical element located adjacent to or disposed on the microLED or the phosphor layer of the pc-microLED. In addition, as shown in FIGS. 4A-4B an array 200 (for example, mounted on an electronics board 300) may be arranged in combination with a light collection optic or optical system (e.g., a projection lens 404). In FIG. 4A, light emitted by microLEDs and/or pc-microLEDs 100 is collected by waveguides or microlenses 402 and directed to projection lens 404. Projection lens 404 may be a Fresnel lens, for example. In FIG. 4B, light emitted by microLEDs and/or pc-microLEDs 100 is collected directly by projection lens 404 without use of intervening optics. This arrangement may be particularly suitable when microLEDs or pc-microLEDs can be spaced sufficiently close to each other. A microLED display application may use optical arrangements similar to those depicted in FIGS. 4A-4B, for example. Generally, any suitable arrangement of optical elements may be used in combination with the microLED and pc-microLED arrays described herein, depending on the desired application.

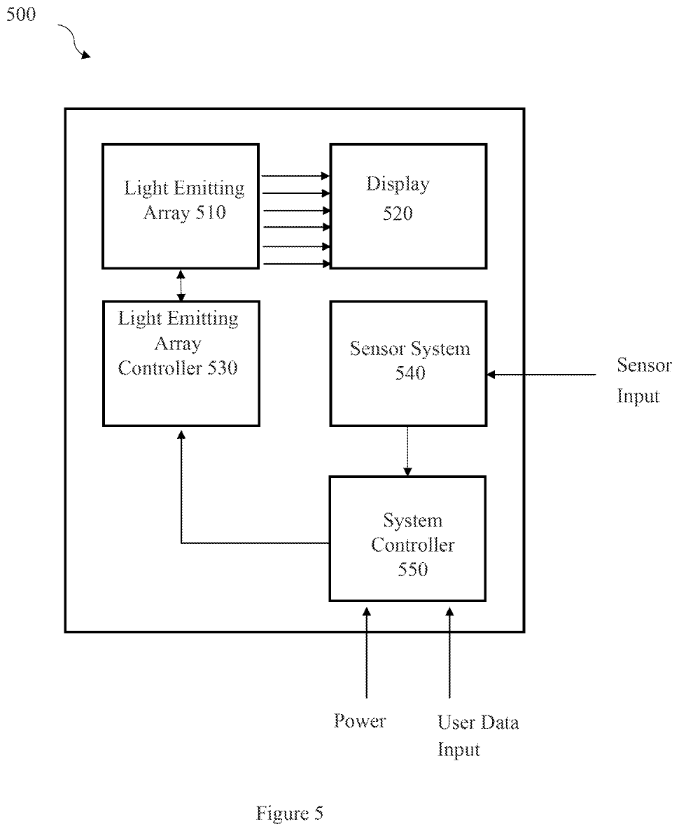

FIG. 5 schematically illustrates an example display (e.g., AR/VR/MR) system 500 that includes a microLED and/or pc-microLED array 510, display 520, a light emitting array controller 530, sensor system 540, and system controller 550. Control input is provided to the sensor system 540, while power and user data input is provided to the system controller 550. In some embodiments modules included in system 500 can be compactly arranged in a single structure, or one or more elements can be separately mounted and connected via wireless or wired communication. For example, the light emitting array 510, display 520, and sensor system 540 can be mounted on a headset or glasses, with the light emitting controller and/or system controller 550 separately mounted. System 500 can incorporate a wide range of optics in light emitting array 510 and/or display 520, for example to couple light emitted by light emitting array 510 into display 520.

Sensor system 540 can include, for example, external sensors such as cameras, depth sensors, or audio sensors that monitor the environment, and internal sensors such as accelerometers or two or three axis gyroscopes that monitor an AR/VR/MR headset position. In some embodiments, control input can include detected touch or taps, gestural input, or control based on headset or display position.

In response to data from sensor system 540, system controller 550 can send images or instructions to the light emitting array controller 530. Changes or modifications to the images or instructions can also be made by user data input, or automated data input as needed. User data input can include but is not limited to that provided by audio instructions, haptic feedback, eye or pupil positioning, or connected keyboard, mouse, or game controller.

As summarized above, this specification discloses AlInGaP microLEDs comprising AlInGaP quantum dots disposed in one or more quantum wells in the microLED light emitting active region. The quantum dots trap and confine carriers (electrons and holes) that are injected into the light emitting active region during operation of the microLED, preventing the confined carriers from moving laterally along the quantum wells to reach nonradiative recombination centers at the perimeter surfaces of the device and thereby increasing the light emitting efficiency of the microLED.

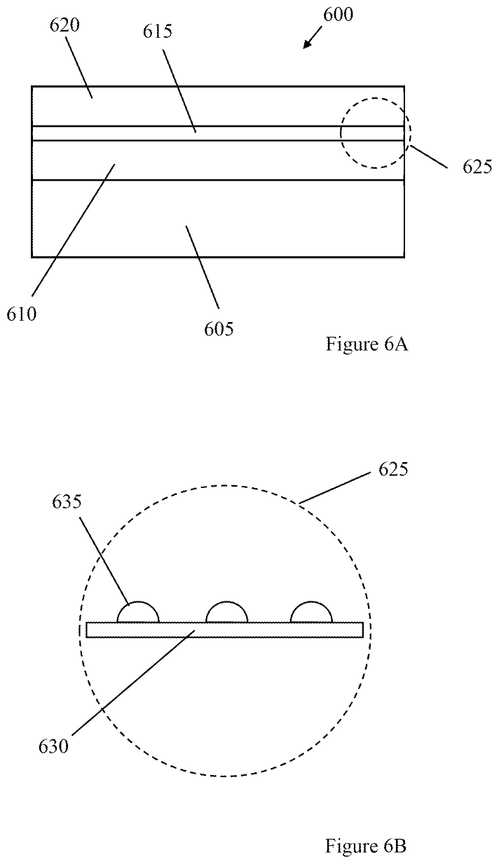

FIG. 6A shows a schematic cross-sectional view of an example 600 of such an AlInGaP microLED structure comprising quantum dots in its active region. MicroLED structure 600 comprises an n-type (AlₓₙGa₁₋ₓₙ)_{yn}In_{1-yn}P layer 610 grown on and typically lattice matched to a crystalline Gallium Arsenide (GaAs) growth substrate 605. An active region 615 comprising one or more (Al_{xqw}Ga_{1-xqw})_{yqw}In_{1-yqw}P quantum well layers is grown on n-type layer 610. A p-type (AlₓₚGa₁₋ₓₚ)_{yp}In_{1-yp}P layer 620 is grown on active region 615 opposite from the n-type layer 610.

After epitaxial growth (e.g., by Metal-Organic Chemical Vapor Deposition) of the stack of layers in this microLED structure, typically a mirror and one or more p-side electrical contacts are formed on the surface of p-type layer 620 opposite from active region 615, GaAs substrate 605 is removed, and one or more n-side electrical contacts are formed on the surface of n-type layer 610 opposite from active region 615. In operation of the microLED, light generated in the active region is emitted through n-type layer 605.

FIG. 6B shows a schematic cross-sectional view of a portion 625 of active region 615 comprising a portion 630 of an (Al_{xqw}Ga_{1-xqw})_{yqw}In_{1-yqw}P quantum well layer and a plurality of compressively strained Ga_{yqd}In_{1-yqd}P quantum dots 635. During epitaxial growth of the active region 615, quantum well material (Al_{xqw}Ga_{1-xqw})_{yqw}In_{1-yqw}P is grown to form portion 630 of a quantum well layer. Quantum dot material Ga_{yqd}In_{1-yqd}P is then grown on the quantum well material. Significantly, the quantum dot material comprises more Indium than does the quantum well material (i.e., yqd<yqw). As a result, lattice mismatch between the crystal structure of the quantum dot material and the crystal structure of the quantum well material causes compressive strain on the quantum dot material that induces it to self-assemble to form discrete quantum dots 635 (e.g., by Stranski-Krastanov growth, known as the SK mode) rather than to form as a continuous layer. After growth of quantum dots 635 additional quantum well material may be grown on top of the exposed portion 630 of the quantum well layer and on the quantum dots 635 to complete the quantum well layer.

Constraints on the subscripts characterizing the compositions of the various materials in microLED structure 600 are presented above in the summary section. For unstrained lattice matched growth to GaAs the composition of an (AlGa)_{y}In_{1-y}P material satisfies 0.50≤y≤0.51. Typically, n-type layer 610 and p-type layer 620 have compositions satisfying this constraint and are lattice matched to GaAs. Quantum well layers within the active region 615 may also have compositions that satisfy this constraint and thus be lattice matched to GaAs. In such cases self-assembly of quantum dots (e.g., the SK mode) can be achieved with quantum dot material satisfying the constraint yqd<0.5, which experiences compressive stress when grown on a layer lattice matched to GaAs. Alternatively, the quantum well material may have a composition for which yqw<0.5 and therefore be compressively strained by a GaAs lattice matched layer on which it is grown. In such cases self-assembly of quantum dots (e.g., the SK mode) can be achieved with quantum dot material satisfying the constraint yqd<yqw<0.5.

The quantum dot material may be, for example, InP. In such cases, in operation the microLED may emit red light having a peak wavelength at or around 650 nm. Such InP quantum dots may be formed for example in Ga_{yqw}In_{1-yqw}P quantum wells. The Ga_{yqw}In_{1-yqw}P quantum wells may for example be grown lattice matched to a GaAs substrate with 0.50≤yqw≤0.51.

The quantum dot material may be, for example, Ga_{yqd}In_{1-yqd}P with 0<yqd<yqw. Such Ga_{yqd}In_{1-yqd}P quantum dots may be formed for example in Ga_{yqw}In_{1-yqw}P quantum wells. Because the quantum dots include some Gallium they have a lattice constant closer to that of the Ga_{yqw}In_{1-yqw}P quantum wells than do InP quantum dots. Consequently, the Ga_{yqd}In_{1-yqd}P quantum dots are less strained than InP quantum dots and as a result can be grown larger in their dimensions. This is one way of controlling quantum dot dimensions. (Generally, the temperature and other parameters in the growth process in combination with the compressive strain resulting from lattice mismatch controls the size of the quantum dots). Also, adding a slight amount of Gallium into InP QDs has an effect of achieving a shorter emission wavelength, which may be more appropriate for display red.

The quantum wells can be compressively strained from a GaAs substrate by using a quantum well material for which 0.4<yqw<0.5 (i.e., more Indium than Gallium). Strain in the quantum wells has an effect of tuning the quantum dot emission wavelength. Quantum well thickness can also be varied to tune the quantum dot emission wavelength.

In some variations the quantum well material is (Al_{0.05}Ga_{0.95})_{0.5}In_{0.5}P and in operation the emission peak is at about 630 nm.

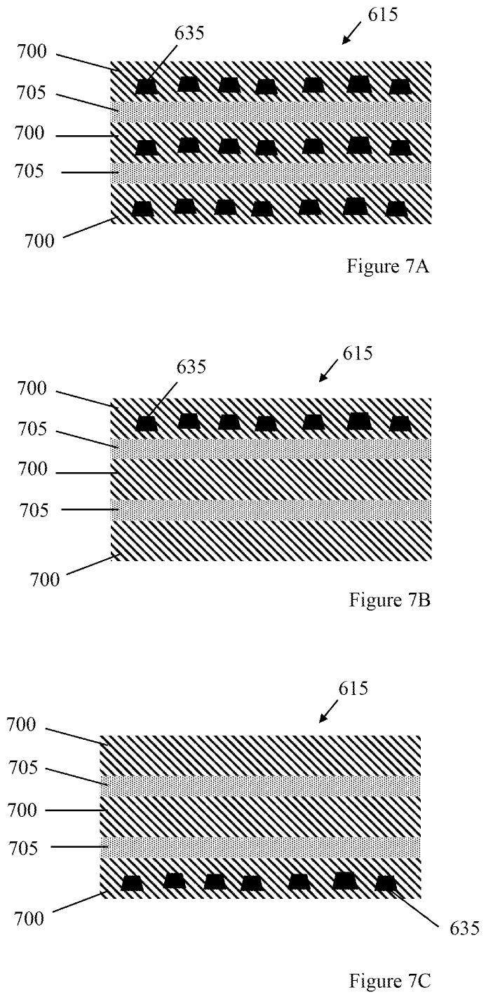

Referring now to FIGS. 7A-7C, active region 615 may comprise a plurality of quantum well layers 700 and one or more quantum barrier layers 705 each disposed between between two adjacent ones of the quantum well layers. Generally, the quantum well layers may have composition (Al_{xqw}Ga_{1-xqw})_{yqw}In_{1-yqw}P and the quantum barrier layers have composition (Al_{xqb}Ga_{1-xqb})_{yqb}In_{1-yqb}P, with xqb>xqw (i.e., more Aluminum in the quantum barrier layers than in the quantum well layers) and 0.3≤xqb≤0.8. Typically the quantum barrier layers have 0.5≤yqb≤0.51 and are therefore lattice matched to GaAs. For example, the quantum barrier layers may have composition (Al_{xqb}Ga_{1-xqb})_{0.5}In_{0.5}P with 0.3≤xqb≤0.8. The quantum dots may have compositions as described above.

Typically, the quantum well layers have a thickness in the growth direction (i.e., perpendicular to the layers) of for example about 1.5 nm to about 10 nm, for example about 3 nm to about 10 nm. The quantum barrier layers have a thickness in the growth direction of for example about 2 nm to about 20 nm. The quantum dots have a lateral dimension parallel to the quantum well layers of for example about 2 nm to about 200 nm.

For convenience of illustration, active regions 615 shown in FIGS. 7A-7C show only three quantum well layers separated by two quantum barrier layers. More generally, active region 615 may comprise for example 3 to 100 periods, where each period is a quantum well and adjacent quantum barrier pair. Quantum barrier layers may be undoped, or doped either n-type or p-type.

Referring now to FIG. 7A, in some variations each of the (Al_{xqw}Ga_{1-xqw})_{yqw}In_{1-yqw}P quantum well layers comprises a plurality of compressively strained Ga_{yqd}In_{1-yqd}P quantum dots disposed in the quantum well layer.

Referring now to FIG. 7B, in some variations only a subset of the (Al_{xqw}Ga_{1-xqw})_{yqw}In_{1-yqw}P quantum well layers located closer to the p-type (AlₓₚGa₁₋ₓₚ)_{yp}In_{1-yp}P layer than to the n-type (AlₓₙGa₁₋ₓₙ)_{yn}In_{1-yn}P layer comprises a plurality of compressively strained Ga_{yqd}In_{1-yqd}P quantum dots disposed in the quantum well layer. For example, if the active region comprises N quantum well layers only the M<N quantum well layers closest to p-type layer 620 (FIG. 6) comprise quantum dots.

Referring now to FIG. 7C, in some variations only a subset of the (Al_{xqw}Ga_{1-xqw})_{yqw}In_{1-yqw}P quantum well layers located closer to the n-type (AlₓₙGa₁₋ₓₙ)_{yn}In_{1-yn}P layer than to the p-type (AlₓₚGa₁₋ₓₚ)_{yp}In_{1-yp}P layer comprises a plurality of compressively strained Ga_{yqd}In_{1-yqd}P quantum dots disposed in the quantum well layer. For example, if the active region comprises N quantum well layers only the M<N quantum well layers closest to n-type layer 610 (FIG. 6) comprise quantum dots.

The composition of the (Al_{xqw}Ga_{1-xqw})_{yqw}In_{1-yqw}P quantum well material may be identical in each quantum well layer or vary through the stack. The composition of the (Al_{xqb}Ga_{1-xqb})_{yqb}In_{1-yqb}P barrier layer material may be identical in each quantum barrier layer or vary through the stack. The composition of the Ga_{yqd}In_{1-yqd}P quantum dots may be the same in each quantum well layer comprising quantum dots or vary between quantum well layers.

During operation of the microLED, electrons and holes are injected into the active region 615 from opposite sides and become trapped and confined in the quantum dots, where they radiatively recombine to emit light. The quantum dots restrict the carriers from moving laterally in the active region and encountering non-radiation recombination sites on perimeter surfaces of the active region. Restricting the quantum dots to only a subset of the quantum wells may better localize light emission and may improve manufacturability. In variations comprising quantum wells that lack quantum dots, those quantum wells may act as a reservoir that feeds carriers into the quantum wells comprising quantum dots which then trap and confine the carriers.

This disclosure is illustrative and not limiting. Further modifications will be apparent to one skilled in the art in light of this disclosure and are intended to fall within the scope of the appended claims.

What is claimed is:

1. A microLED comprising:
a stack of semiconductor layers comprising
an n-type (AlₓₙGa₁₋ₓₙ)_{yn}In_{1-yn}P layer;
a p-type (AlₓₚGa₁₋ₓₚ)_{yp}In_{1-yp}P layer; and
an active region disposed between the n-type (AlₓₙGa₁₋ₓₙ)_{yn}In_{1-yn}P layer and the p-type (AlₓₚGa₁₋ₓₚ)_{yp}In_{1-yp}P layer and comprising at least one (Al_{xqw}Ga_{1-xqw})_{yqw}In_{1-yqw}P quantum well layer; and
a plurality of compressively strained Ga_{yqd}In_{1-yqd}P quantum dots disposed in the quantum well layer;
wherein
0≤xn≤1;
0≤ yn<1;
0≤ xp≤1;
0≤ yp<1;
0≤ xqw≤0.3;
0≤ yqw<1; and
0≤ yqd<yqw.

2. The microLED of claim 1, wherein xn=xp=1.

3. The microLED of claim 1, wherein 0.50≤yn≤0.51 and 0.50≤yp≤0.51.

4. The microLED of claim 1, wherein 0.50≤yqw≤0.51.

5. The microLED of claim 1, wherein 0.40≤yqw≤0.5.

6. The microLED of claim 1, wherein 0≤yqd<0.5.

7. The microLED of claim 1, wherein yqd=0.

8. The microLED of claim 1, wherein yqd>0.

9. The microLED of claim 1, wherein:
0.50≤yn≤0.51 and 0.50≤yp≤0.51;
0.50≤yqw≤0.51; and
0≤yqd<0.5.

10. The microLED of claim 9, wherein yqd=0.

11. The microLED of claim 9, wherein yqd>0.

12. The microLED of claim 1, wherein:
0.50≤yn≤0.51 and 0.50≤yp≤0.51; and
0.40≤yqw≤0.5.

13. The microLED of claim 12, wherein yqd=0.

14. The microLED of claim 12, wherein yqd>0.

15. The microLED of claim 1, wherein the at least one (Al_{xqw}Ga_{1-xqw})_{yqw}In_{1-yqw}P quantum well layer is one of a plurality of (Al_{xqw}Ga_{1-xqw})_{yqw}In_{1-yqw}P quantum well layers, comprising:
one or more (Al_{xqb}Ga_{1-xqb})_{yqb}In_{1-yqb}P quantum barrier layers each disposed between two adjacent ones of the quantum well layers;
wherein xqb>xqw.

16. The microLED of claim 15, wherein each of the (Al_{xqw}Ga_{1-xqw})_{yqw}In_{1-yqw}P quantum well layers comprises a plurality of compressively strained Ga_{yqd}In_{1-yqd}P quantum dots disposed in the quantum well layer.

17. The microLED of claim 15, wherein only a subset of the (Al_{xqw}Ga_{1-xqw})_{yqw}In_{1-yqw}P quantum well layers located closer to the n-type (AlₓₙGa₁₋ₓₙ)_{yn}In_{1-yn}P layer than to the p-type (AlₓₚGa₁₋ₓₚ)_{yp}In_{1-yp}P layer comprises a plurality of compressively strained Ga_{yqd}In_{1-yqd}P quantum dots disposed in the quantum well layer.

18. The microLED of claim 15, wherein only a subset of the (Al_{xqw}Ga_{1-xqw})_{yqw}In_{1-yqw}P quantum well layers located closer to the p-type (AlₓₚGa₁₋ₓₚ)_{yp}In_{1-yp}P layer than to the n-type (AlₓₙGa₁₋ₓₙ)_{yn}In_{1-yn}P layer comprises a plurality of compressively strained Ga_{yqd}In_{1-yqd}P quantum dots disposed in the quantum well layer.

19. The microLED of claim 1, configured to emit red light during operation.

20. A display device comprising a plurality of microLEDs as in claim 1 configured and arranged as pixel red emitters.
